(19) United States
(12) Patent Application Publication
(10) Pub. No.: US 2002/0179245 A1
(43) Pub. Date: Dec. 5, 2002

(54) Plasma processing apparatus and maintenance method therefor

(76) Inventors: Toshio Masuda, Toride (JP); Hiroshi Kanekiyo, Kudamatsu (JP); Tetsuo Fujimoto, Hikari (JP); Mitsuru Suehiro, Kudamatsu (JP); Katsuji Matano, Kudamatsu (JP); Kazue Takahashi, Kudamatsu (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/202,094

(22) Filed: Jul. 25, 2002

Related U.S. Application Data
(62) Division of application No. 09/936,766, filed on Sep. 17, 2001.

(30) Foreign Application Priority Data
Mar. 17, 1999 (JP) 11-72577

(51) Int. Cl. C23F 1/00; C23C 16/00

(52) U.S. Cl. 156/345.1; 118/715

(57) ABSTRACT

A maintenance method including performing a maintenance operation for a plasma processing apparatus having a vacuum vessel having a formed processing chamber inside, a plasma generation device for generating plasma in the processing chamber, and an electrode for holding a sample to be processed in the processing chamber. The plasma processing chamber is structured so that an upper wall of the vacuum vessel is an open-close part, and at least one of parts constituting the plasma generation device including a non-metallic brittle member is arranged in the open-close part, and at least one part of an upper wall constituting an upper side surface of the processing chamber is rotated around an almost horizontal axis and the open-close part can be held stably in a state that the open-close part on an inner side of the processing chamber is directed upward.

### CROSS REFERENCE TO RELATED APPLICATION

This is a divisional of U.S. application Ser. No. 09/936,766, filed Sep. 17, 2001, the subject matter of which is incorporated by reference herein.

### BACKGROUND OF THE INVENTION

The present invention relates to a plasma processing apparatus and a maintenance method therefor; and, more particularly, the invention relates to a plasma processing apparatus and a maintenance method which are suitable for forming a fine pattern in a semiconductor manufacturing process.

In a semiconductor manufacturing process, a plasma processing apparatus is widely used for fine processing, such as film forming, etching, and ashing. Such a plasma processing apparatus is described in, for example, Japanese Application Patent Laid-Open Publication No. Hei 07-161695 (hereinafter called Prior Art 1) and Japanese Application Patent Laid-Open Publication No. Hei 05-335263 (hereinafter called Prior Art 2).

In Prior Art 1, a plasma processing method for use in a high frequency induction coupling system having quartz glass on the upper part of the processing chamber is disclosed. Further, in Prior Art 2, a plasma processing apparatus is disclosed in which a ceiling cover is installed in the processing chamber so as to be capable of being opened by rotating around a hinge, and a plasma enhancement magnetic field coil is supported independently of the ceiling cover and is movable, so as to make it possible to open the upper part of the processing chamber.

During plasma processing using such a plasma processing apparatus, plasma gas, which is introduced into the vacuum vessel (reactor), is made plasmatic by the plasma generation means and reacts on the semiconductor wafer surface so as to perform fine processing, and volatile reaction products are exhausted, whereby a predetermined process is performed.

In using this plasma processing apparatus to perform plasma processing, a problem arises in that, when a sample is being processed, reaction products are deposited on the surface around the lower electrode for loading the sample, which reaction products eventually separate from the surface around the lower electrode and adhere onto the wafer surface as particles, causing a reduction in yield. Therefore, it is necessary to periodically perform a cleaning operation, called wet cleaning, which involves exposing the plasma processing apparatus to the air and removing the deposits. Further, parts exposed to the plasma in the vacuum vessel are consumed as the process is repeated, so that the consumable parts must be exchanged periodically.

Such a technique concerning maintenance inside the vacuum vessel is described in, for example, Japanese Application Patent Laid-Open Publication No. Hei 07-147241 (hereafter called Prior Art 3) and Japanese Application Patent Laid-Open Publication No. Hei 10-41096 (hereafter called Prior Art 4).

In Prior Art 3, a maintenance mechanism is disclosed for moving the whole wafer stage (on which a wafer is loaded with its surface facing down), installed on the upper part of the processing chamber, using a vertical moving mechanism and a horizontal moving mechanism. In Prior Art 3, an open-close part on the upper part of the vacuum vessel functions as a wafer holding mechanism capable of moving vertically and horizontally. In Prior Art 3, the stage installed on the open-close upper part is composed of a mechanism, that is, machine parts.

Further, in Prior Art 4, an apparatus is disclosed in which the upper exhaust chamber UC, the processing chamber PC, and the lower exhaust chamber DC are structured so as to separate, and the upper exhaust chamber UC can be moved up and down freely and can be turned upside down by a rotation mechanism. For example, as shown in FIG. 6 of the publication, the upper exhaust chamber can be moved up and down freely and can be turned upside down using a rotation mechanism. The wall of the upper exhaust chamber UC functions as a cover.

As another method for ensuring the workability at the time of maintenance inside the vacuum vessel, a method has been adopted in which the upper wall of the vacuum vessel is structured so as to be capable of being opened and closed using a mechanism, such as a hinge, whereby the upper part of the vacuum vessel can be opened at an angle of about 90 degrees to an almost upright position, so that maintenance, including the exchange of parts, can be performed.

However, when the upper wall of the vacuum vessel is in an almost upright position, as mentioned above, there is the possibility that, when a set screw for an exchange part is removed, the part will not remain in place independently and may become dislocated. Therefore, at the time of mounting or demounting of an exchange part, an operator must support the part by hand, which results in a difficult operation, even if a part attaching jig is used. There is also the possibility that various faults may occur, such as the part position being shifted at the time of attaching the part, or excessive force being applied to the part at the time of tightening a set screw, causing chipping, or a uniform force not being applied to the part, so that the part is damaged due to a thermal stress cycle during operation.

Particularly, for example, in a silicon oxide film etching device, for the antenna of the upper part of the vacuum vessel and the upper electrode, non-metallic brittle parts, such as an expensive and fragile silicon shower plate and a quartz ring, are typically used. Further, even in a magnetron type plasma processing apparatus and a parallel plate type plasma processing device, for a part of the upper electrode and gas feed means, non-metallic brittle parts, such as silicon and quartz parts, are used. When these parts are to be exchanged, if the vacuum vessel is opened only up to 90 degrees, parts being removed or inserted may be dropped, or excessive force may be applied, or the parts may be damaged.

In addition, as the wafer diameter is increased, there is a tendency for the components in the vacuum vessel to be made larger, causing the weight to be increased, so that there is a tendency that handling of parts is more difficult for an operator, and the burden on the operator is increased more and more. To avoid such a situation, it has been proposed that two persons performs the operation instead one person. However, in this case, excessive persons are required for maintenance, resulting in an increase in personnel expenses.

The present invention was developed to solve the aforementioned problems and is intended to provide a plasma processing apparatus having an improved maintainability and operability at the time of exchange of consumables in the vacuum vessel and during wet cleaning, thereby contributing to an increase in productivity, and a maintenance method therefor.

The present invention is particularly intended to provide a plasma processing apparatus which has excellent maintainability of the processing chamber, providing the possibility of using non-metallic brittle materials for parts of the vacuum vessel, and a maintenance method therefor.

### SUMMARY OF THE INVENTION

To accomplish the above objects, a characteristic of the present invention resides in the fact that the plasma processing apparatus has movable closed vessels arranged in correspondence with a plurality of evacuation modules having evacuation chambers for evacuating samples, switch means for opening and closing the closed vessels, and means installed between each of the closed vessels and each of the evacuation chambers of the evacuation modules for transferring samples in or out of the closed vessels via the switch means.

Further, another characteristic of the present invention resides in the fact that the plasma processing apparatus has movable closed vessels arranged in correspondence with a plurality of evacuation modules having evacuation chambers for evacuating samples, means for moving the closed vessels to positions corresponding to the evacuation modules, switch means for opening and closing the closed vessels, and means installed between each of the closed vessels and each of the evacuation chambers of the evacuation modules for transferring samples in or out of the closed vessels via the switch means.

Still another characteristic of the present invention resides in the fact that, in a maintenance method for a plasma processing apparatus having a vacuum vessel having a processing chamber formed inside, a plasma generation device for generating plasma in the processing chamber, and an electrode for holding a sample to be processed in the processing chamber, the plasma processing chamber is structured so that the upper wall of the vacuum vessel is provided as an open-close part, and at least one of the parts constituting the plasma generation device, including a non-metallic brittle member, is arranged in the open-close part, and at least one part of the upper wall constituting the upper side surface of the processing chamber is capable of being rotated around an almost horizontal axis so that the open-close part can be held stably in a state in which parts on the inner side of the processing chamber are directed upward with the surface thereof held at an angle of less than 30 degrees from the horizontal plane when the open-close part is opened, whereby a maintenance operation for the plasma processing apparatus can be performed easily and efficiently.

To hold the aforementioned parts stably and naturally when the open-close part is opened, it is desirable to keep the open-close part on the inner side of the processing chamber at an angle of less than 30 degrees from the horizontal plane.

A further characteristic of the present invention resides in the fact that the opening direction of the open-close part is lowered the direction of the maintenance operation area.

A still further characteristic of the present invention resides in the fact that the power supply to the open-close part is structured so as to be connected to the open-close part in a removable way and to be easily joined and separated and structured so that only when this connection is joined, an interlock mechanism is released and power can be supplied from the power supply, and, furthermore, when the power supply is separated, the hot side terminal of the open-close part is grounded.

According to the present invention, in a plasma processing apparatus in which the upper wall of the vacuum vessel can be opened or closed, and in which at least one of the parts constituting the plasma generation device, including a non-metallic brittle member, is arranged, the upper wall of the vacuum vessel on the inner side of the processing chamber can be kept flat in an open state, that is, within a range of less than 30 degrees from the horizontal position. Therefore, the maintenance operation in the vacuum vessel can be performed easily. Within the range of less than 30 degrees, the non-metallic brittle parts constituting the upper wall can be held physically stable by friction.

In the embodiment of the present invention, plasma is generated by supplying power to the antenna installed on the upper part of the reactor, and the antenna itself, which is a plasma generation device, can be opened or closed.

According to the present invention, when the non-metallic brittle parts are to be demounted or mounted to the upper wall, even if the set screws are all removed, the non-metallic brittle parts are held in an almost horizontal state relative to the antenna in the upper wall and the upper electrode is held physically stable by a frictional force.

According to the present invention, among the parts constituting the plasma generation device, for example, the non-metallic brittle parts, which are a part of the constituent materials of the antenna, such as quartz and silicon, are hardly broken, and the upper wall can be handled easily. Namely, when the non-metallic brittle parts are to be demounted or mounted, the parts are held horizontally, so that, for example, during the demounting or mounting operation, no excessive force is applied to the set screws and no parts are dropped by mistake. Thus, an effect is produced in which even the non-metallic brittle parts, such as quartz and silicon, are not broken and damaged.

Further, the inside parts are held almost flat with the surface thereof directed upward, so that the posture of the operator performing maintenance is comfortable and the workability is improved. By doing this, the maintenance operation inside the vacuum vessel, particularly for the plasma generation device, is easy. Namely, the operator performing a parts exchange operation can demount or mount the parts and perform a handling operation in a comfortable position, so that there is an advantage that the physical and mental burden imposed on the operator can be greatly reduced.

Particularly, since the plasma generation device is complicated in structure and the method of the mounting each of the parts is difficult, when the device is held in a horizontal position, there is no fear of dropping of parts, and parts can be exchanged while the operator is in a comfortable position.

A still further characteristic of the present invention resides in the fact that the power supply to the coil and plasma generation device is structured so as to be capable of being separated from the upper wall using a removable connection part, so that the maintenance operation for the upper wall, including a non-metallic brittle member, can be performed more easily. Furthermore, only when the removable connection part is joined can power be supplied from the power supply; and, when the power supply is separated, the hot side terminal of the connection part of the open-close part is brought into contact with the grounding part, so that no power is supplied in an insufficient connection state and no operator comes in contact with the charged part, whereby the safety of the apparatus and the operator can be ensured.

### BRIEF DESCRIPTION OF DRAWINGS

FIG. 1 is a schematic diagram of an embodiment in which the present invention is applied to a plasma etching device of a magnetic field UHF band electromagnetic wave radiation-discharge system.

FIG. 2 is a schematic diagram illustrating the maintenance method for the plasma etching device of this embodiment.

FIG. 3 is a schematic diagram illustrating the maintenance method for the plasma etching device of this embodiment.

FIG. 4 is a schematic diagram illustrating the maintenance method for the plasma etching device of this embodiment.

FIG. 5 is a diagram showing connection of an introduction terminal of the plasma etching device of this embodiment.

FIG. 6 is a diagram showing the detailed connection of the introduction terminal shown in FIG. 5.

FIG. 7 is a schematic diagram showing the condition at the time of the maintenance operation for the plasma etching device of this embodiment.

FIG. 8 is a schematic diagram showing the condition at the time of the maintenance operation for a conventional plasma etching device.

FIG. 9 is a schematic diagram showing an embodiment in which a vacuum vessel having a full-flat open structure in accordance with the present invention is loaded on a plasma processing apparatus system.

FIG. 10 is a diagram showing an embodiment of a hinge mechanism of the plasma processing apparatus of the embodiment shown in FIG. 1.

FIG. 11 is a diagram showing an embodiment in which the present invention is applied to an RIE device (for example, a magnetron RIE device) using a magnetic field.

FIG. 12 is a diagram showing an example in which the present invention is applied to a parallel-plate type plasma processing apparatus.

### BEST MODE FOR CARRYING OUT THE INVENTION

Various embodiments of the present invention will be explained hereunder with reference to the accompanying drawings.

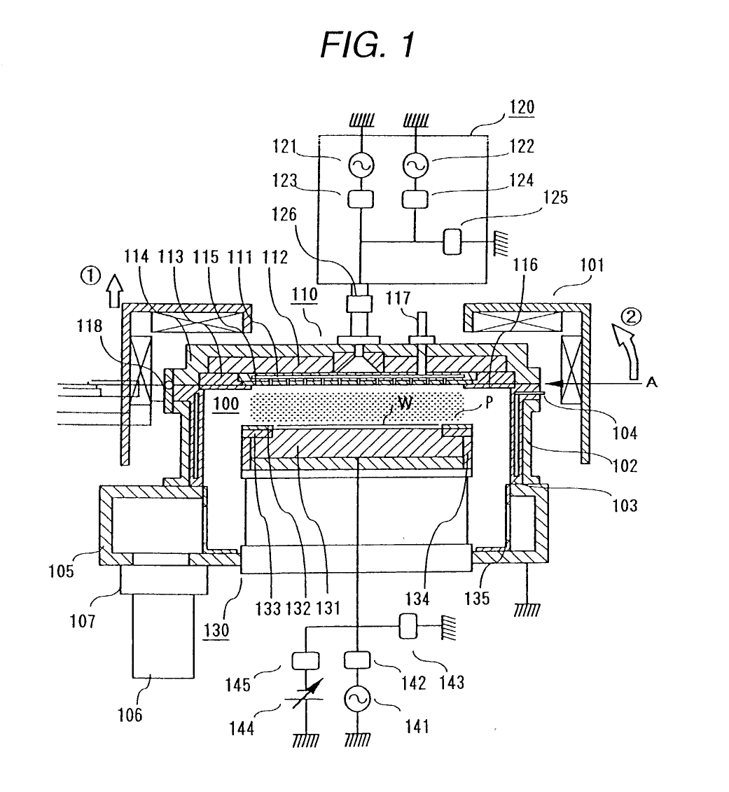

The constitution of an apparatus representing a first embodiment will be explained in detail with reference to FIG. 1, and then the methods proposed for parts exchange and maintenance will be explained more specifically.

FIG. 1 shows an embodiment in which the present invention is applied to a plasma etching device having a magnetic field UHF band electromagnetic wave radiation-discharge system. A processing chamber 100, which forms a vacuum vessel capable of realizing a degree of vacuum of about 10-6 Torr, has an antenna 110 for radiating electromagnetic waves on the upper part thereof and a lower electrode 130 for loading a sample W, such as a wafer, on the lower part thereof. The antenna 110 and the lower electrode 130 are installed in parallel with and opposite to each other. Around the processing chamber 100, for is example, a magnetic field forming means 101, composed of an electromagnetic coil and a yoke, is installed. By the interaction between electromagnetic waves radiated from the antenna 110 and the magnetic field formed by the magnetic field forming means 101, process gas introduced into the processing chamber is changed to a plasma, so as to generate plasma P, and the sample W is processed.

The processing chamber 100 is evacuated by an evacuation system 106 connected to a vacuum chamber 105, and the pressure is controlled by a pressure control means 107. The vacuum chamber 105 is set at ground potential. On a side wall 102 of the processing chamber 100, a side wall inner unit 103 is installed in an exchangeable state, and a heating medium is circulated and fed from a heating medium feed means 104 to the inner unit 103, so that the temperature of the inner surface thereof is controlled within the range from 0° C. to 100° C., preferably from 20° C. to 80° C., with an accuracy of less than ±10° C. Or, the temperature of the inner surface of the unit 103 may be controlled by a heating mechanism and a temperature detection means. For the side wall 102 and the side wall inner unit 103, it is desirable to provide a surface treatment, such as plasma-resistant anodized aluminum, on the surface, for example, a layer of aluminum.

The antenna 110 is composed of a circular conductor 111, a dielectric plate 112 and a dielectric ring 113, and it is held by a housing 114 forming a part of the vacuum vessel. On the side of the circular conductor 111 in contact with the plasma, a plate 115 is installed; and, moreover, on the outside thereof, a peripheral ring 116 is installed. The circular conductor 111 is adjusted in temperature by a temperature control means (not shown in the drawing) and the surface temperature of the plate 115 in contact with the circular conductor 111 is controlled. Process gas for etching a sample is fed from a gas feed means 117 at a predetermined flow rate and mixing ratio, and this gas is fed into the processing chamber 100 via a plurality of holes formed in the circular conductor 111 and the plate 115.

It is suitable to use, for example, silicon or carbon for the plate 115 and, for example, quartz or alumina for the peripheral ring 116. In this embodiment, silicon is used for the plate 115 and quartz is used for the peripheral ring 116.

The antenna 110 is attached to the side wall 102 by a hinge 118; and, it is separated from the side wall 102 at the position indicated by the arrow A and lifted upward, then rotated in the direction of the arrow (2) around a fulcrum of the rotation axis of the hinge 118, which is installed almost horizontally, thereby allowing the housing 114 to be opened at an angle of about 180 degrees (the position indicated by a dashed line in the drawing). Even if the set screws of the plate 115 and the peripheral ring 116 are removed in this state, the antenna is held in a physically stable state by friction or by a joint, such as a level difference in height, for example, several mm to about 10 mm. To open the antenna 110, the magnetic field forming means 101 is moved upward in the direction of the arrow (1) beforehand and withdrawn to a position free of interference with the antenna so as to provide no obstacle to maintenance.

To the antenna 110, as an antenna power system 120, an antenna power source 121 and an antenna bias power source 122 are connected to a power input terminal 126 via matching circuit-filter systems 123 and 124, and they are connected to ground via a filter 125. The antenna power source 121 supplies power at a UHF band frequency of 300 MHz to 1 GHz. In this embodiment, the frequency of the antenna power source 121 is set to 450 MHz. On the other hand, the antenna bias power source 122 applies bias power within the frequency range from several tens kHz to several tens MHz to the antenna 110. In this embodiment, the frequency is set at 13.56 MHz. The distance from the bottom of the plate 115 to the wafer W (hereinafter called a gap) is 30 mm to 150 mm, preferably from 50 mm to 120 mm.

On the lower part of the processing chamber 100, the lower electrode 130 is installed opposite to the antenna 110. To the lower electrode 130, a bias power source 141 for supplying bias power within the range, for example, from 400 kHz to 13.56 MHz, is connected via a matching circuit-filter system 142, and it controls the bias to be applied to the sample W and is connected to the ground via a filter 143. In this embodiment, the frequency of the bias power source 141 is set at 800 kHz.

The lower electrode 130 loads and holds the sample W, such as a wafer, on the top thereof, that is, on the sample loading surface, using an electrostatic chucking device 131. On the surface of the electrostatic chucking device 131, an electrostatic chucking film is formed; and, when a DC voltage of several hundreds V to several kV is applied to it from an electrostatic chucking DC power source 144 and a filter 145, the sample W is chucked and held on the lower electrode 130 by the electrostatic chucking force. On the top of the electrostatic chucking device 131 and on the outer side of the sample W, for example, a silicon focus ring 132 is installed, and this ring 132 is insulated from the electrostatic chucking device 131 by an insulator 133. Outside the electrode, an electrode peripheral cover 134 is installed. It is suitable to use alumina or quartz for the electrode peripheral cover 134. Furthermore, a lower cover 135 is installed on the inner surface of the lower part of the processing chamber.

The plasma etching device of this embodiment is structured as mentioned above. A process of etching, for example, a silicon oxide film, using this plasma etching device, will be explained with reference to FIG. 1.

Firstly, the wafer W, which is an object to be processed, is transferred into the processing chamber 100 from a sample transfer mechanism (not shown in the drawing) and is loaded and chucked on the lower electrode 130. The height of the lower electrode is then adjusted as required and a predetermined gap is obtained. Then, a mixed gas necessary for the etching of the sample W, for example, C4F8, Ar, and O2, is fed into the processing chamber 100 from the gas feed means 117 via the plate 115. At the same time, the processing chamber 100 is adjusted to a predetermined processing pressure by the evacuation system 106.

Next, electromagnetic waves are radiated by power supplied at 450 MHz from the antenna power source 121. By the interaction with the almost horizontal magnetic field of 160 gauss (intensity of the electron cyclotron magnetic field for 450 MHz) formed inside the processing chamber 100 by the magnetic field forming means 101, plasma P is generated in the processing chamber 100, and the process gas is dissociated and radical ions are generated. Furthermore, ions and radicals are controlled by the antenna bias power from the antenna bias power source 122 and the bias power from the bias power source 141 from the lower electrode, and the wafer W is etched. When the etching process is finished, the supply of power, the magnetic field and the supply of process gas are stopped. and the etching is finished.

The etching of a wafer by the plasma processing apparatus in this embodiment is performed as mentioned above. As the process is repeated, reaction products are deposited slowly in the processing chamber, and the deposited film eventually peels off, with the result that foreign substances are generated. At the point of time when the number of particles of this foreign substance exceeds a certain control standard (for example, 20 particles with a diameter of 0.2 μm per wafer or less), the processing chamber is exposed to the air and subjected to wet cleaning.

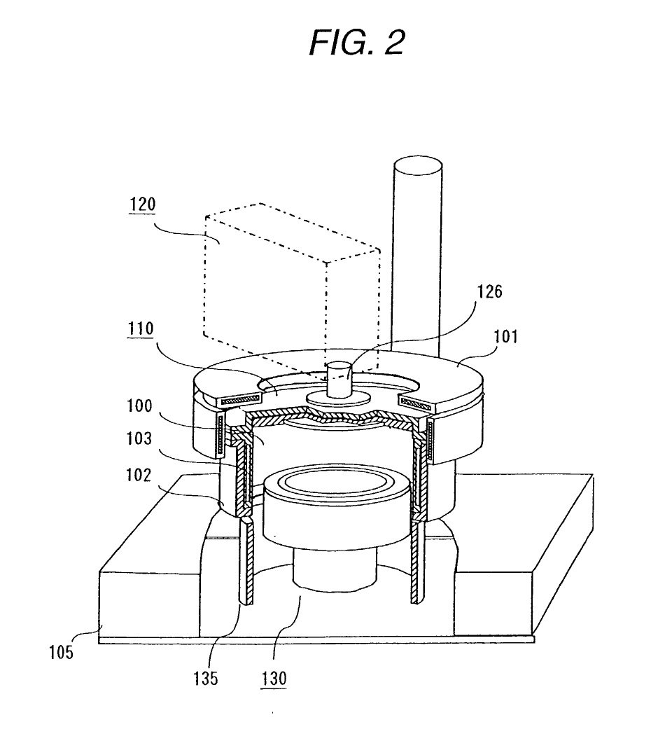

Next, the rough procedure for disassembly and assembly of the apparatus and a parts removal method employed at the time of wet cleaning of the apparatus of this embodiment will be explained with reference to FIGS. 2 to 7.

FIG. 2 is a perspective view of a section of the plasma etching device shown in FIG. 1, which is shown schematically so as to illustrate the maintenance condition in accordance with the present invention, and a part thereof is shown in a section. The antenna 110 is attached onto the side wall 102 supported on the vacuum chamber 105; the magnetic field forming means 101 is installed around it; and, the antenna power source system 120 is connected to the antenna 110 via the power input terminal 126.

At the time of disassembly of the apparatus for performing wet cleaning, the processing chamber 100 and the vacuum chamber 105 are exposed to the air, and the connection of the power input terminal 126 for connecting the antenna 110 to the antenna power source system 120 is released.

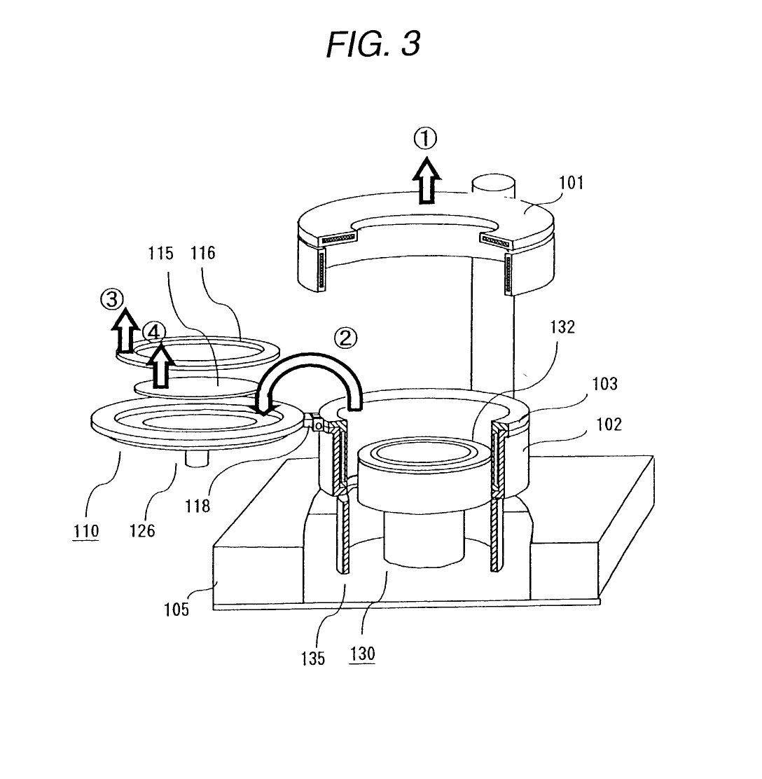

The next step is shown in FIG. 3. First, as shown by the arrow (1) in FIG. 3, the magnetic field forming means 101 and the antenna power source system 120 (not shown in the drawing) are moved up and fixed at positions where they no longer represent an obstacle to the maintenance operation. Then, as shown by the arrow (2), the antenna 110 is rotated around the axis of the hinge 118 so that it is opened and held in an almost horizontal position, and the plate 115 and the ring 116 are removed in an upward direction, as shown by the arrows (3) and (4).

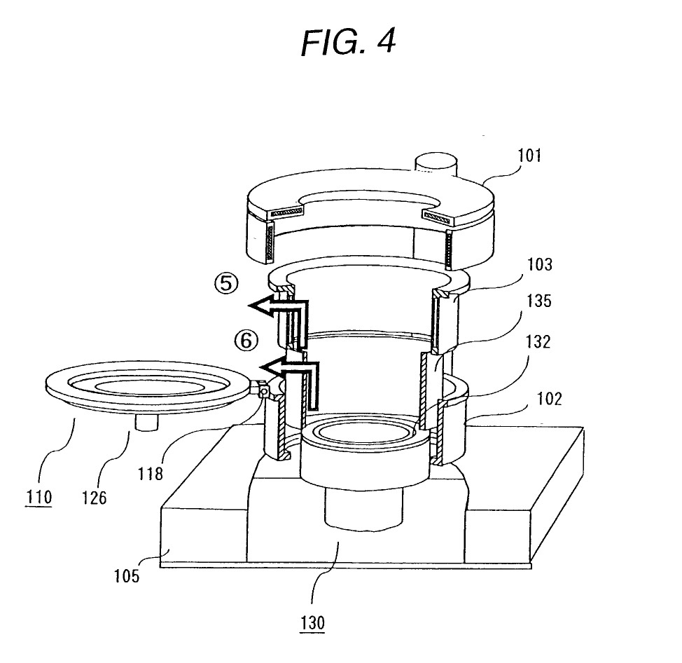

The next step is shown in FIG. 4 by the arrows (5) and (6), in which the side wall inner unit 103 and the lower cover 135 are pulled upward and removed. Further, with respect to the lower electrode, the focus ring 132 and the electrode peripheral cover 134 are removed. The removed parts are subjected to processes for removal of a deposited film and for ultrasonic cleaning and drying. Then, the parts are attached using the reverse of the aforementioned procedure, and the device is returned to its original condition and evacuated.

Thereafter, when it is ascertained that the degree of vacuum of the processing chamber 100 has reached a predetermined value, a performance confirmation, such as a particles check and etching rate check, is performed as required, and the operation of the device is ascertained. The device is then returned to its normal operating condition, and the wet cleaning operation is completed. When a set of exchange parts is prepared beforehand, the device can be returned and evacuated immediately, so that the down time of the device can be shortened.

Furthermore, by fixing the sealing part of the vacuum flange by clamps instead of bolts, the workability of wet cleaning can be improved. Thus, the parts exchange operation can be performed in 1.5 to 2 hours, and the down time (good wafer to good wafer) of the device, including the operation confirmation, such as the evacuation and particles and rate check is suppressed to about 3 to 4 hours, whereby the operation rate of the device is reserved.

In this embodiment, as shown in FIG. 3, the antenna 110 is structured so as to rotate around the axis of the hinge 118 and open, so that there is no need to lift up and remove the whole antenna 110 from the processing chamber, whereby the burden of lifting up a heavy article is not imposed on the operator. As mentioned already, when the plate 115, which is a silicon shower plate, and the quartz ring 116 are to be removed, they may be lifted upward as shown by the arrows (3) and (4) in FIG. 4 and the workability is good, so that the operating efficiency can be increased and the possibility of damage to the parts is reduced.

Further, in this embodiment, the antenna power source system 120 on the upper part of the processing chamber is structured so as to be connected to the power input terminal 126 in a way that it can be joined to and removed from the antenna 110 easily, so that the antenna 110 can be opened to an almost horizontal position. The power input terminal 126 is structured so that the hot side terminal on the inner side to supply power and the ground terminal on the outer side are insulated. When the connection of the power input terminal 126 is released, the hot side terminal on the inner side of the antenna 110 is structured so as to come in contact with the grounding part on the outer side using a simple mechanism, such as a grounding cable or a spring. The antenna 110 may be charged by friction with the inner wall surface of the cooling medium flow path due to a cooling medium circulating inside the antenna. However, the antenna is connected to the ground; therefore, thus even if the antenna is charged, the charge is released, and even if an operator touches the hot side terminal by mistake, the safety of the operator is ensured.

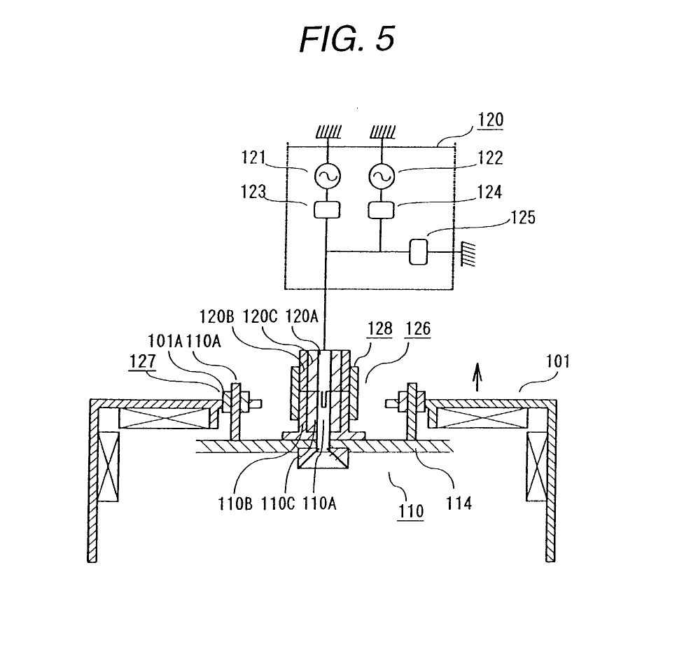

The structure and method for separation and connection of the power input terminal 126 will be explained with reference to FIG. 5. As previously explained with reference to FIG. 1, the antenna power source system 120 and the antenna 110 (only a part is shown in FIG. 5) are connected via the power input terminal 126 in a removable way so as to be connected and disconnected easily. However, the antenna power source system 120 and the magnetic field forming means 101 can be arranged move up and down as a unit. Therefore, when the connection of the power input terminal 126 is to be released, the antenna power source system 120 and the magnetic field forming means 101 are moved up as a unit, and the antenna power source system 120 and the antenna 110 are separated.

On the other hand, to connect the power input terminal 126 to the antenna power source system 120, the antenna power source system 120 and the magnetic field forming means 101 are moved down as a unit. However, in this case, it is necessary to connect the antenna power source system 120 to the power input terminal 126 smoothly. For that purpose, the relative position of the magnetic field forming means 101 and the antenna 110 is determined by a positioning mechanism 127.

Here, as a positioning mechanism 127, a vertical bar 110A is installed on the antenna 110 and a sleeve 101A is installed on the magnetic field forming means 101. When the antenna power source system 120 and the magnetic field forming means 101 move down as a unit, they are mutually positioned by a plurality of sets of vertical bars 110A and sleeves 101A, and the central axis of the antenna 110 accurately coincides with the central axis of the magnetic field forming means 101. As a result, the mating and connection thereof at the power input terminal 126, which will be described next, can be carried out smoothly, free of displacement.

Next, the detailed structure of the power input terminal 126 will be explained with reference to FIG. 5. The power input terminal 126 has a structure in which a coaxial tube for transferring UHF band electromagnetic waves is connected. Central conductors (hot side terminals) 120A and 110A of the antenna power source system 120 and the antenna 110, respectively, and outer ground shields 120B and 110B are insulated via insulators 120C and 110C. When the antenna power source system 120 and the magnetic field forming means 101 move down, the central conductors 120A and 110A are mated and joined; and, at this point of time, a position sensor (not shown in the drawing) detects the stop position, and the descending stops. The ground shields 120B and 110B are disposed outside thereof and connected by a connection unit 128.

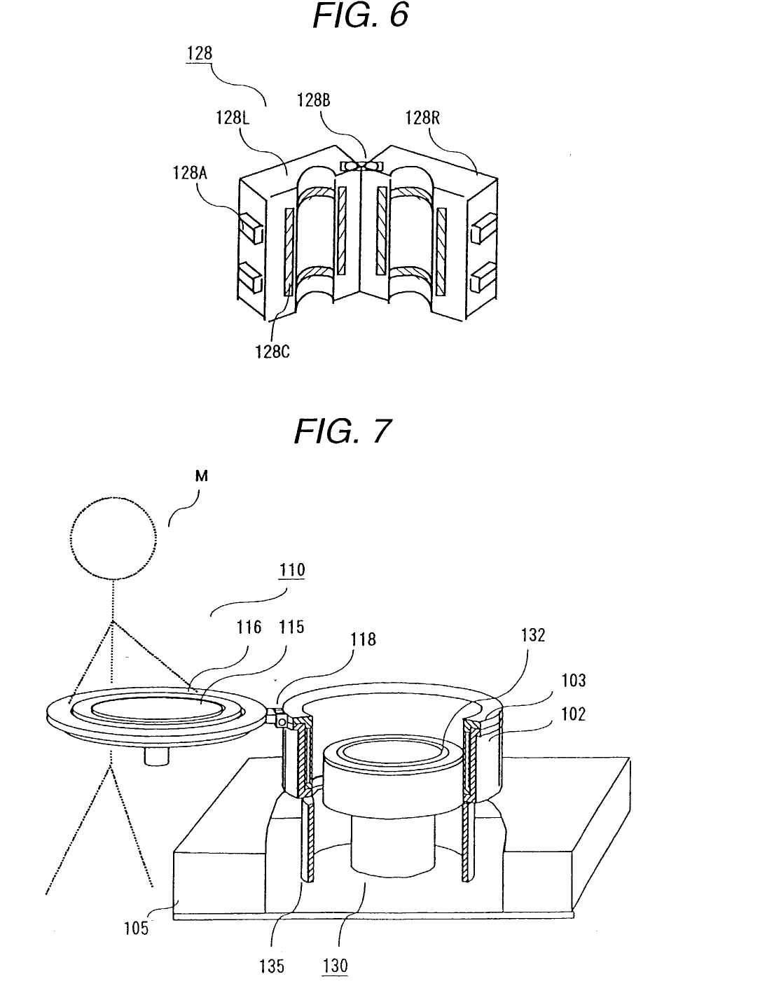

The connection unit 128, as shown in FIG. 6, is structured as a releasable clamp 128A, consisting of two units 128L and 128R which rotate around a hinge 128B. The units 128L and 128R, which form divided left and right portions, have a semicircular groove at the center of the inner surface thereof, respectively, so that when the clamp 128A is closed, the left and right semicircular grooves join together to form a circular passage for holding the ground shields 120B and 110B shown in FIG. 5. In this case, in order to ensure contact between the ground shields 120B and 110B and prevent leakage of UHF band electromagnetic waves, electromagnetic shields 128C are installed on the mutual contact surfaces of the units 128L and 128R and on the upper and lower parts of the semicircular grooves. For the electromagnetic shields 128C, for example, a cushioning wire mesh or a more rigid finger type or spiral electromagnetic shielding member is suitable.

Furthermore, the clamp 128A has a built-in interlock switch (not shown in the drawing) and is structured so that, when the clamp is fixed, the interlock is released and power from the antenna power source system 120 shown in FIG. 5 can be input to the antenna 110. Needless to say, to release the interlock, it is necessary to allow the antenna power source system 120 and the magnetic field forming means 101 to move down to predetermined positions. By these interlock mechanisms, even if an operator forgets to join the power input terminal 126 and the connection unit 128 at the time of wet cleaning, no power can be input from the antenna power source system 120 by the fail safe interlock mechanism.

In this embodiment, the antenna itself, which is a plasma generation device installed on the upper part of the reactor and is supplied with power, can be opened and closed. Therefore, for example, in contrast to the structure shown in Prior Art 2, when the antenna is structured so that not only the coil, but also the antenna 110, can be moved up and down, and the antenna power source system 120 can be joined or separated easily, a satisfactory maintainability can be realized for the first time.

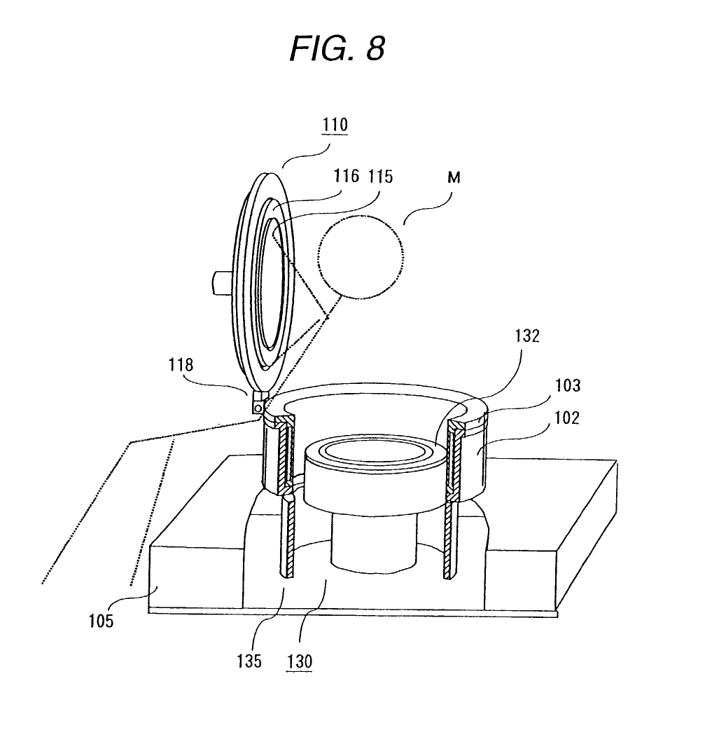

The constitution of the plasma etching device and the methods for parts exchange and maintenance in this embodiment are as mentioned above. As mentioned above, the adoption of the full-flat open structure improves the workability of parts exchange and maintenance. This can be understood more clearly by reference to FIGS. 7 and 8, which schematically show the posture of an operator and the operating condition at the time of maintenance.

FIG. 7 schematically shows the maintenance condition during the full-flat open state of the plasma etching device of the embodiment shown in FIG. 1. In FIG. 7, the antenna 110 for radiating electromagnetic waves is attached to the side wall 102 by the hinge 118, so that it is capable of being opened at an angle of almost 180 degrees. FIG. 7 shows a situation in which, in the full-flat open state, the antenna 110 is opened at about 180 degrees and the inner side of the antenna is directed upwardly and is disposed almost horizontally, so that the peripheral ring 116 of the antenna 110 and the inner peripheral plate 115 can be removed.

In this embodiment, the peripheral ring 116 is a quartz ring, and the plate 115 is a silicon shower plate having many bored gas holes. They are expensive parts which are easily broken and damaged. However, when the antenna 110 to which they are attached is rotated to the open position where it is disposed almost horizontally, an operator M can attach and handle these parts from above in a comfortable position. Further, even in a case where the set screws of the parts are all removed, the parts are held almost horizontally, that is, in a physically stable state, by friction or a stopper, and so there is no need to support the parts.

Therefore, as shown in FIG. 7, the operator M can handle the parts with both hands, so that there is no need to worry about the parts slipping-down. Further, at the time of attaching the parts, excessive force need hardly be applied to the screws, so that the parts will not be damaged. Further, since the opening direction of the antenna 110 is set to lie in a direction toward the operator in the maintenance area, the antenna 110 is held in a position of easy access by the operator, so that the operator can operate in a stable position. Needless to say, no additional operator or helper is necessary.

For comparison, in this embodiment, a case in which maintenance is performed in a state wherein the processing chamber is almost upright at an open angle of about 90 degrees, like the prior art, is shown in FIG. 8. When the quartz peripheral ring 116 and the silicon plate 115 are to be removed, if the set screws are removed, the parts are able to fall out of place. Therefore, the operator M must remove the set screws by pressing the parts using one hand, so that the workability is not good. Moreover, there is the possibility of the parts slipping down. Or, excessive force may be applied to the screw holes at the time of attaching the parts and the parts may be easily damaged. The operator M may be concerned and fear the possibility of damage of expensive and fragile quartz and silicon parts. Further, since the inner surface of the antenna 110 is not opposite to the operator, he or she needs to lean over the body of the equipment, and the burden imposed on the operator is great as a result.

Comparison of such aspects shows that the full-flat open structure shown in FIG. 7 is excellent in the maintainability. This can be really appreciated by performing a maintenance operation on the device, and it can be easily inferred that this structure greatly reduces the burden imposed on the operator, increases the operation efficiency, and thereby contributes to improvement of the productivity.

By use of the full-flat open structure for a part of the processing chamber, even in a plasma processing apparatus system having a loaded vacuum vessel (reactor) composed of an inner plasma processing chamber, the whole arrangement and maintenance can be carried out in a well-balanced state.

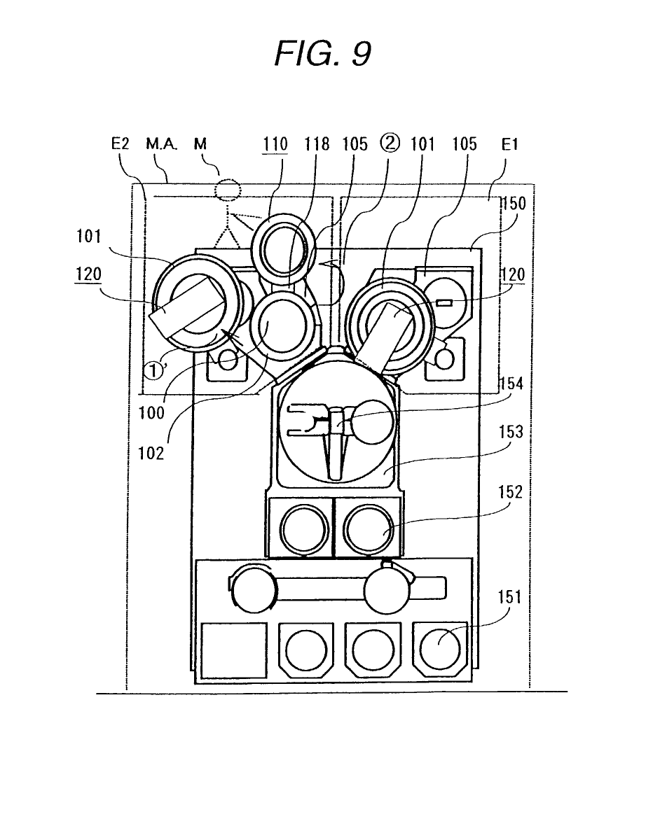

FIG. 9 shows another embodiment of the present invention in which a vacuum vessel having a full-flat open structure is loaded in a plasma processing apparatus system. FIG. 9 is a plan view as viewed from above. This apparatus has two plasma processing chambers E1 and E2. A sample wafer is transferred into a buffer chamber 153 from a loader mechanism 151 via a load lock chamber 152 and is transferred into the plasma processing chambers E1 and E2 by a sample transfer mechanism 154.

The plasma processing chamber E1 is in a state such that the apparatus is assembled and the magnetic field forming means 101 and the antenna power source system 120 are loaded on the vacuum chamber 105. The plasma processing chamber E2 is in a state during the wet cleaning operation in which the inside of the processing chamber 100 is exposed to the air, and the antenna 110 is opened in a full-flat state by rotating it around the hinge 118. The magnetic field forming means 101 and the antenna power source system 120 are withdrawn to positions where they are not an obstacle to the maintenance operation. The antenna 110 is opened toward the operator M (the outer direction of a base frame 150) in the maintenance area (here, the area having a width of about 80 cm around the apparatus is called a maintenance area) and about a half thereof is projected from the base frame 150 of the system, so that the operator M can perform the maintenance operation easily. Further, the antenna 110 is not projected excessively in the maintenance area and does not occupy space in the clean room excessively. The clean room is an expensive space because the degree of cleanness is maintained by a down flow. Therefore, it is required for the apparatus not only to occupy a small floor area (foot print) in the operating state, but also to reduce the apparatus interval as much as possible. Therefore, it is typical in a mass production factory that only a minimum space necessary for maintenance and passing, for example, a space having a width of about 80 cm, is provided around the apparatus. Therefore, it is desirable as a mass production apparatus from the viewpoint of effective use of the clean room space that the reactor is projected by half at most, even during the maintenance provided by this embodiment, that is, only about several tens cm at most. Further, in Prior Art 3, the whole wafer stage is moved by the vertical moving mechanism and horizontal moving mechanism, while in Prior Art 4, the exhaust chamber is rotated by the vertical moving mechanism and rotation mechanism. However, such mechanisms are on a large-scale, and the moving mechanisms are projected around the apparatus during maintenance, so that compactness of the whole apparatus may be lost. From this viewpoint, in this embodiment, there is no need to pull out the processing chamber using a pull-out mechanism or to lift up the antenna using a vertical moving mechanism, such as a crane. When the plasma processing chamber (reactor) having a full-flat open structure is loaded like this, a well-balanced plasma processing apparatus system having the compactness of the whole arrangement and good maintainability can be realized.

Meanwhile, in the plasma processing apparatus of the embodiment shown in FIG. 1, a heating medium for controlling the temperature of the circular conductor 111 is fed to the antenna 110. In this case, if the heating medium feed path (for example, a hose) is engaged or disengaged by a connection part, such as a connector, when the antenna 110 is rotated into a full-flat open in which that it is opened at 180 degrees, the cooling medium may leak from the sealing part of the connector and an excessive maintenance operation time may be needed. Further, as the antenna is opened at 180 degrees and closed repeatedly, so that the hose for feeding a heating medium is bent greatly each time, such repeated bending of the hose may cause the hose to be damaged. Therefore, when an introduction path for a heating medium is installed in the hinge 118 for opening and closing the antenna, even when the antenna is to be opened or closed, there is no need to engage or disengage the connection part. Thus, an improvement of the reliability against leakage of the cooling medium due to damage of the connection sealing part or hose and a shortening of the maintenance operation time can be realized.

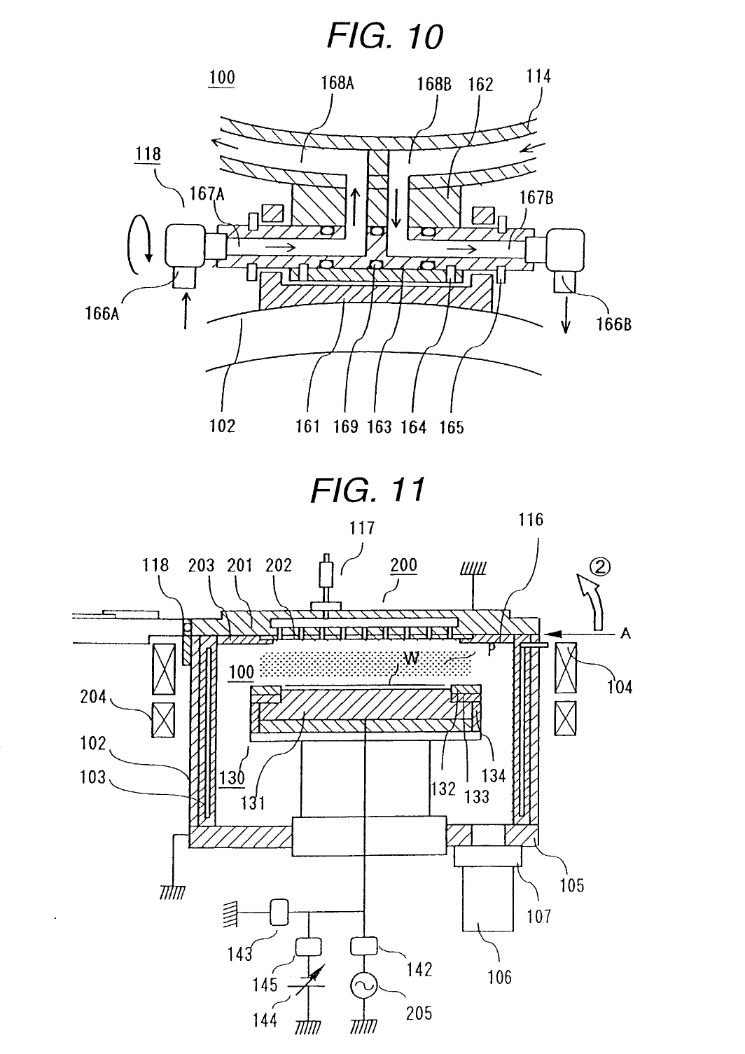

FIG. 10 shows an embodiment of such a hinge mechanism. FIG. 10 is a cross sectional view of the structure of the hinge 118, which is capable of opening and closing at almost 180 degrees and in which the heating medium flow path is installed. In FIG. 10, the hinge 111 is viewed from above in a state that it is opened at 180 degrees. To the housing 114 of the antenna 100, a support part 162 is attached and fixed to a shaft 163 by stoppers 164, such as set screws. The shaft 163 is attached rotatably to a hinge mounting part 161, which is attached to the side of the side wall 102, and the movement in the axial direction is restricted by a stopper 165, for example, a lock ring, so that the mutual positional relationship is determined.

A heating medium flows in a flow path 168A inside the antenna housing 114 through a flow path 167A in the shaft from a universal coupling 166A, which is rotatable around the axis of the shaft 163, and the heating medium is ejected from a flow path 166B via flow paths 168B and 167B. The flow paths for the heating medium are sealed by seal members 169, such as O-rings, so as to prevent the heating medium from leaking. As a heating medium, for example, Florinat (a brand name) is used, and it is suitable to set the temperature thereof within the range from 30° C. to 80° C. or so.

According to this embodiment, when the antenna is to be opened, there is no need to engage or disengage a connector for connecting a heating medium passage, so that leakage of the cooling medium from the sealing part of the connector can be prevented. Thus, the reliability of the maintenance operation can be improved and the operation time can be shortened.

In the respective embodiments mentioned above, a plasma processing apparatus having a magnetic field UHF band electromagnetic wave radiation-discharge system is used. However, the electromagnetic waves to be radiated may be electromagnetic waves of other than the UHF band, for example, 2.45 GHz microwaves or electromagnetic waves of the VHF band within the range from several tens MHz to about 300 MHz may be used. Further, with respect to the magnetic field intensity, a case of 160 gauss, which is an electron cyclotron resonance magnetic field intensity for 450 MHz, has been proposed. However, there is no need to use the resonance magnetic field always, and a magnetic field stronger than it or conversely a weak magnetic field of several tens of gauss or less may be used. Furthermore, for example, a non-magnetic field microwave using no electromagnetic field may be radiated. Furthermore, in addition to the aforementioned, for example, to a magnetron type plasma processing apparatus using a magnetic field, a plasma processing apparatus of a parallel plate type capacity coupling system, or an inductive coupling type plasma processing apparatus, may be employed in each of the aforementioned embodiments.

FIG. 11 shows an embodiment in which the present invention is applied to an RIE device (for example, a magnetron RIE device) using a magnetic field. In this embodiment, the processing chamber 100 in the form of a vacuum vessel has a side wall 102, a lower electrode 130 for loading a sample W, such as a wafer, and an upper electrode 200 grounded opposite to it; and, it also has gas feed means 117 for introducing predetermined gas into the vacuum vessel, an evacuation system 106 for evacuating the vacuum vessel, a lower power source 205 for supplying power to the lower electrode, and magnetic field generation means 204 for generating a magnetic field in the vacuum vessel.

The magnetic field generation means 204 has a plurality of permanent magnets or coils arranged in a ring-shape in the periphery or above the processing chamber 100, and it forms a magnetic field almost parallel with the electrode in the processing chamber. The magnetic field is inclined so as to rotate. Process gas is changed to plasma by an electric field generated between the electrodes by power supplied from the lower power source 205, and a plasma P is generated, whereby the sample W is processed. In the RIE device using a magnetic field, a magnetic field is formed almost perpendicularly to the electric field by the magnetic field generation means 204, so that the collision frequency of electrons with molecules and atoms in the plasma is increased by the magnetic field and the magnetron effect, and the plasma density is increased, and a high etching characteristic is obtained. The frequency of the lower power source 205 is preferably within the range from the low frequency band to the high frequency band, such as from several hundreds of kHz to several tens of MHz.

The plate 202 having a grounded electrode plate 210 with many gas holes formed therein is attached to the upper electrode 200, and the upper electrode is covered by the peripheral ring 203. For the plate 202, silicon and carbon are suitable or anodized aluminum may be used. The upper electrode 200 is attached to the side wall 102 by the hinge 118. The upper electrode is separated and lifted up from the side wall 102 at the location indicated by the arrow A, and it is rotated around the almost horizontal support shaft of the hinge 118 as a fulcrum, so that it can be opened at almost 180 degrees (the position indicated by a dashed line in the drawing).

By use of this constitution, when the plate 202 and the peripheral ring 203 are to be removed or exchanged, the upper electrode 200 can be operated on from above in a full-flat open state, so that the workability is good, and the maintenance operation efficiency is improved, and the reliability and safety can be ensured. Further, the possibility of damage due to dropping of parts or application of excessive force is reduced. Furthermore, there is no need to lift up and remove the whole upper electrode 200, so that a burden of lifting up a heavy article is not imposed on the operator. In this embodiment, no power source is connected to the upper electrode 200, so that, in contrast to the embodiment shown in FIG. 1, there is no need to separate the power source from the terminal, which results in an advantage of further improvement of the workability.

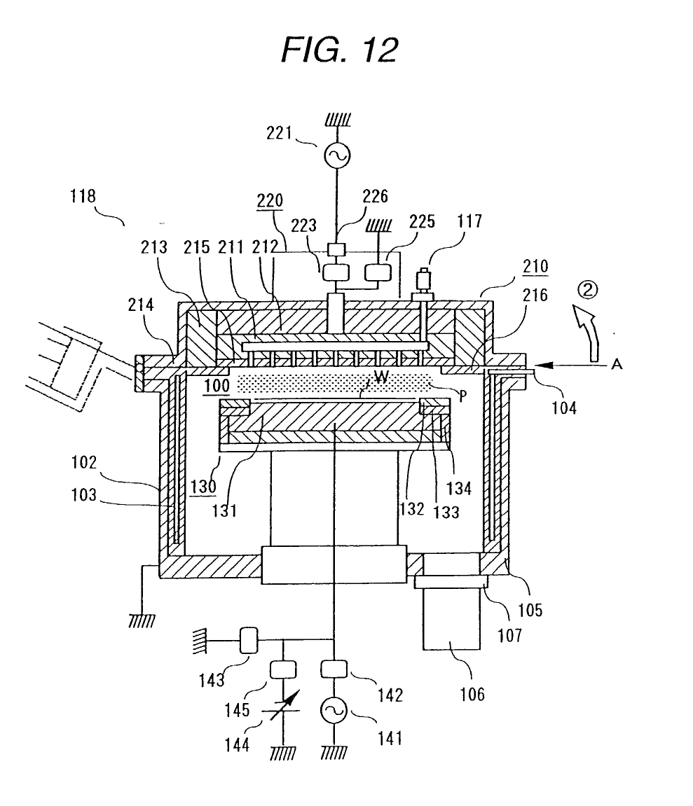

FIG. 12 shows an example in which the present invention is applied to a parallel plate type plasma processing apparatus. In this embodiment, the processing chamber 100 in the form of a vacuum vessel has a side wall 102, a lower electrode 130 for loading a sample W, such as a wafer, and an upper electrode 210 grounded opposite to it; and, it also has a gas feed means 117 for introducing a predetermined gas into the vacuum vessel and an evacuation system 106 for evacuating the vacuum vessel. An electric field is generated between the electrodes by power supplied to the upper electrode 210 from the upper power source 221, whereby process gas is made plasmatic, a plasma P is generated, and the sample W is processed.

The upper electrode 210 is held in the housing 214 in a state in which the electrode plate 211 is insulated by the insulators 212 and 213. The plate 215 is installed on the surface of the electrode plate 211 on the side in contact with the plasma, and the shield ring 216 is installed on the periphery thereof. The shield ring 216 protects the insulators 212 and 213 from plasma and simultaneously encloses the plasma P in the processing chamber 100 together with the focus ring 132, with the result that the plasma density is improved and a high etching characteristic is obtained. It is preferable to use, for example, silicon or carbon for the plate 215 and, for example, quartz or aluminum for the shield ring 216.

The frequency of the upper electrode 221 is preferably within the range from a high frequency band of about 10 MHz to a VHF band of more than 100 MHz. In such a high frequency band or a VHF band, from the viewpoint of the skin effect and power loss in the contact part, it is desirable to connect the electrode plate 211 to the matching circuit-filter system 223 and the filter 225 at the shortest distance possible and to surely join them using a copper plate or a copper pipe. Accordingly, this embodiment uses a constitution in which the matching box 220 comprises a compact and light matching circuit-filter system 223, using a switching circuit of a diode, and a filter 225, and the matching box 220 is directly loaded on the upper part of the upper electrode 210 and is connected to the upper power source 221 by the connection terminal 226.

This embodiment uses a constitution in which the upper electrode 210 is attached to the side wall 102 by the hinge 118, so that it can be separated and lifted up from the side wall 102 at the location indicated by the arrow A, and rotated and opened around the almost horizontal support shaft of the hinge 118 as a fulcrum. And, the matching circuit-filter system 223 loaded on the upper electrode 210 and the filter 225 are made compact and light in weight, so that the upper electrode 210 can be opened at an opening angle of 165 degrees to 180 degrees, that is, within 15 degrees from the horizontal without removing these elements from the upper electrode 210.

By use of this constitution, even if the set screws are removed, for example, when the silicon plate 215 or the quartz insulator 216 is to be exchanged, the part is held in a physically stable state by friction or a stopper, so that there is an advantage in that the possibility of damage due to application of excessive force to a part or dropping of parts is reduced. Further, an operator can operate from above, so that the workability is good, and there is no need to lift up and remove the upper electrode 210, so that there is an advantage that no burden is imposed on the operator.

In this embodiment, the upper power source 221 is structured so as to separate by the connection terminal 226. However, the upper power source 221, which is highly efficient, compact, and light in weight, may be loaded directly on the upper part of the upper electrode 210. In this case, it is possible to set the open angle to about 150 degrees to 180 degrees, that is, within 30 degrees from the horizontal, whereby the exchange operation for the plate 215 and the insulator 216 can be performed efficiently and safely.

Further, there is no need to separate the upper electrode 221 at the connection terminal, so that there is an advantage that the workability is further improved.

Further, in the respective embodiments described above, the objects to be processed are all semiconductor wafers and an etching process for them has been described. However, the present invention is not limited to such processing of wafers; and, for example, the present invention can be applied also to a case in which processing object is a liquid crystal substrate, and the process itself is not limited to etching. For example, the process can be applied also to sputtering or the CVD process.

According to the present invention, a part of the vacuum vessel constituting the processing chamber is structured as a part which can be opened or closed, and the open-close part is held in a physically stable state by friction or a stopper with the part thereof on the processing chamber side directed upward. Therefore, the upper part of the processing chamber can be opened in the maintenance operation area, so that the operator can easily access the processing chamber and can perform a maintenance operation from above in a comfortable position. As a result, the operator can handle the parts easily at the time of maintenance, so that the workability is improved. Thus, a plasma processing apparatus that is superior in maintainability and operability can be realized, and a plasma processing apparatus for contributing to improvement of the productivity can be provided.

What is claimed is:

1. A maintenance method for a plasma processing apparatus having a vacuum vessel having a formed processing chamber inside, a plasma generation device for generating plasma in said processing chamber, and an electrode for holding a sample to be processed in said processing chamber, wherein said plasma processing chamber is structured so that an upper wall of said vacuum vessel is an open-close part, and at least one of parts constituting said plasma generation device including a non-metallic brittle member is arranged in said open-close part, and at least one part of an upper wall constituting an upper side surface of said processing chamber is rotated around an almost horizontal axis and said open-close part can be held stably in a state that said open-close part on an inner side of said processing chamber is directed upward, and said open-close part on said inner side of said processing chamber is kept at an angle of less than 30 degrees from a horizontal plane with said part held when said open-close part is opened, and said open-close part is opened at an angle that said open-close part on said inner side of said processing chamber is directed upward with said part kept, and a maintenance operation for said plasma processing apparatus is performed.

2. A maintenance method for a plasma processing apparatus according to claim 1, wherein said open-close part is opened toward a maintenance operation area and said maintenance operation for said plasma processing apparatus is performed.
